(19) United States
(12) Patent Application Publication
(10) Pub. No.: US 2014/0269039 A1
(43) Pub. Date: Sep. 18, 2014

(54) ELECTRONIC DEVICE AND VARIABLE RESISTANCE ELEMENT

(71) Applicant: SK hynix Inc., Icheon-Si (KR)

(72) Inventors: Kwan-Woo Do, Icheon-Si (KR); Ki-Seon Park, Icheon-Si (KR); Bo-Mi Lee, Icheon-Si (KR); Woon-Joon Choi, Icheon-Si (KR); Sung-Joon Yoon, Icheon-Si (KR); Guk-Cheon Kim, Icheon-Si (KR)

(73) Assignee: SK HYNIX INC., Icheon-Si (KR)

(21) Appl. No.: 14/207,286

(22) Filed: Mar. 12, 2014

(30) Foreign Application Priority Data
Mar. 12, 2013 (KR) 10-2013-0026142

(51) Int. Cl. G11C 11/15; H01L 43/02

(52) U.S. Cl. CPC G11C 11/15; H01L 43/02
USPC 365/158; 257/421

(57) ABSTRACT

A variable resistance element includes: first and second magnetic layers having a lanthanide series element alloyed in a nickel-iron compound; and a tunnel barrier layer interposed between the first and second magnetic layers.

### CROSS-REFERENCE TO RELATED APPLICATIONS

This patent document claims priority of Korean Patent Application No. 10-2013-0026142, entitled “SEMICONDUCTOR DEVICE AND METHOD FOR MANUFACTURING THE SAME, AND MICRO PROCESSOR, PROCESSOR, SYSTEM, DATA STORAGE SYSTEM AND MEMORY SYSTEM INCLUDING THE SEMICONDUCTOR DEVICE,” and filed on Mar. 12, 2013, which is incorporated herein by reference in its entirety.

### TECHNICAL FIELD

This patent document relates to electronic devices, semiconductor circuits and semiconductor fabrication technology, including electronic devices and semiconductor memory devices based on variable resistance elements.

### BACKGROUND

Recently, as electronic devices or appliances trend toward miniaturization, low power consumption, high performance, multi-functionality, and so on, there is a demand for semiconductor devices capable of storing information in various electronic devices or appliances such as a computer, a portable communication device, and so, and research and development for such electronic devices have been conducted. Examples of such semiconductor devices include semiconductor devices which can store data using a characteristic switched between different resistant states according to an applied voltage or current, and can be implemented in various configurations, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device which includes a variable resistance element having magnetic layers capable of minimizing lattice mismatch between a tunnel barrier layer and the magnetic layers.

In one aspect, a variable resistance element is provided to include: first and second magnetic layers including a nickel-iron compound and a lanthanide series element alloyed in the nickel-iron compound; and a tunnel barrier layer interposed between the first and second magnetic layers.

In another aspect, an electronic device is provided to include a variable resistance element that includes: first and second magnetic layers formed over a substrate including a switching element and having a lanthanide series element alloyed in a nickel-iron compound; and a tunnel barrier layer interposed between the first and second magnetic layers; and a conducive line connected to the variable resistance element.

In another aspect, an electronic device is provided to include a semiconductor memory including a variable resistance element; and a conductive line connected to the variable resistance element, wherein the semiconductor memory includes first and second magnetic layers including a nickel-iron compound and a lanthanide series element alloyed in the nickel-iron compound; and a tunnel barrier layer interposed between the first and second magnetic layers.

In some implementations, the first and second magnetic layers may include NiFeLa alloy. In some implementations, the tunnel barrier layer may include aluminum oxide (AlO) or magnesium oxide (MgO).

In some implementations, the electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory is part of the memory unit in the microprocessor.

In some implementations, the electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory is part of the cache memory unit in the processor.

In some implementations, the electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory is part of the auxiliary memory device or the main memory device in the processing system.

In some implementations, the electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory is part of the storage device or the temporary storage device in the data storage system.

In some implementations, the electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory is part of the memory or the buffer memory in the memory system.

In another aspect, a method for fabricating a variable resistance element is provided to include: forming a first magnetic layer over a substrate, the first magnetic layer having a lanthanide series element alloyed in a nickel-iron compound; forming a tunnel barrier layer over the first magnetic layer; forming a second magnetic layer over the tunnel barrier layer; and patterning the second magnetic layer, the tunnel barrier layer, and the first magnetic layer.

In another aspect, a method for fabricating a variable resistance element is provided to include: forming a first magnetic layer over a substrate, the first magnetic layer having a lanthanide series element alloyed in a nickel-iron compound; forming a tunnel barrier layer over the first magnetic layer; forming a second magnetic layer over the tunnel barrier layer; and patterning the second magnetic layer, the tunnel barrier layer, and the first magnetic layer to form a plurality of pillar-type variable resistance elements where each pillar-type variable resistance element is formed to include the first magnetic layer, the tunnel barrier layer, and the second magnetic layer and is spaced from adjacent pillar-type variable resistance elements.

In another aspect, a method for fabricating an electronic device is provided to include: forming a variable resistance element over a substrate including a switching element, the variable resistance element including first and second magnetic layers having a lanthanide series element alloyed in a nickel-iron compound and a tunnel barrier layer interposed between the first and second magnetic layers; and forming a conductive line connected to the variable resistance element.

In some implementations, the tunnel barrier layer may include AlO or MgO. In some implementations, the tunnel barrier layer may be formed through a sputtering or oxidation process. In some implementations, the first and second magnetic layers may include NiFeLa alloy. In some implementations, the first and second magnetic layers may be formed through physical vapor deposition (PVD) equipment. In some implementations, the second magnetic layer may include the same material as the first magnetic layer.

In yet another aspect, a variable resistance element is provided to include: first and second magnetic layers, each magnetic layer including first and second elements exhibiting magnetism; and a tunnel barrier layer interposed between the first and second magnetic layers, wherein the first and second elements are selected to cause a corresponding magnetic layer to have a reduced or minimized lattice mismatch between the first and second magnetic layers and the tunnel barrier layer.

In some implementations, the first and second elements include a nickel-iron compound. In some implementations, the first and second magnetic layers further include a third element to reduce a specific resistance of each layer. In some implementations, the third element include a lanthanide series element. In some implementations, the first and second magnetic layers include NiFeLa alloy. In some implementations, the tunnel barrier layer includes aluminum oxide (AlO) or magnesium oxide (MgO).

These and other aspects, implementations and associated advantages are described in greater detail in the drawings, the description and the claims.

### BRIEF DESCRIPTION OF THE DRAWINGS

FIG. 1 is a cross-sectional view of a variable resistance element in accordance with an implementation.

FIG. 2 is a cross-sectional view of an electronic device in accordance with an implementation.

FIGS. 3A to 3D are cross-sectional views illustrating a method for fabricating an electronic device in accordance with an implementation.

FIGS. 4A and 4B and FIGS. 5A and 5B are cross-sectional views and conceptual views for comparing the variable resistance element in accordance with the present implementation to a variable resistance element in accordance with a comparative example.

FIG. 6 is an example of configuration diagram of a microprocessor implementing memory circuitry based on the disclosed technology.

FIG. 7 is an example of configuration diagram of a processor implementing memory circuitry based on the disclosed technology.

FIG. 8 is an example of configuration diagram of a system implementing memory circuitry based on the disclosed technology.

FIG. 9 is an example of configuration diagram of a data storage system implementing memory circuitry based on the disclosed technology.

FIG. 10 is an example of configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

The present implementations provide an electronic device including a variable resistance element capable of increasing an integration degree by improving device characteristics and a method for fabricating the electronic device. In general, a variable resistance element has a stacked structure of two magnetic layers with a tunnel barrier layer interposed therebetween. Due to the lattice mismatch between the magnetic layers and the tunnel barrier layer caused by differences in the material compositions, a compressive stress exists at the tunnel barrier layer. In presence of this compressive stress, electron scattering occurs and causes the sheet resistance (RA) to undesirably increase and the tunnel magneto-resistance (TMR) to undesirably decrease. Certain implementations of the disclosed technology can include an electronic device including a variable resistance element capable of minimizing the lattice mismatch between the magnetic layers and the tunnel barrier layer and reducing sheet resistance and a method for fabricating the electronic device.

FIG. 1 is a cross-sectional view of a variable resistance element in accordance with an implementation of the disclosed technology in this patent document.

Referring to FIG. 1, the variable resistance element 100 is formed over a substrate 11, and may include a stacked structure of a first magnetic layer 12, a tunnel barrier layer 13, and a second magnetic layer 14. Although not illustrated, the variable resistance element 100 may further include an electrode for applying a bias to the variable resistance element 100 and a template layer, a coupling layer, and an interface layer for improving the characteristics of the respective magnetic layers. The substrate 11 may include a switching element (not illustrated) and a contact plug for connecting a junction region of the switching element to the variable resistance element 100.

The variable resistance element 100 having a stacked structure of the first magnetic layer 12, the tunnel barrier layer 13, and the second magnetic layer 14 is referred to as a magnetic tunnel junction (MTJ). The variable resistance element 100 including the two magnetic layers 12 and 14 with the tunnel barrier layer 13 interposed therebetween may have a characteristic switched between different resistance states according to the magnetization directions of the two magnetic layers 12 and 14. For example, when the magnetization directions of the two magnetic layers 12 and 14 are identical to each other (or parallel to each other), the variable resistance element 100 may have a low resistance state, and when the magnetization directions of the two magnetic layers 12 and 14 are different from each other (or anti-parallel to each other), the variable resistance element 100 may have a high resistance state.

One of the first and second magnetic layers 12 and 14 may include a pinned ferromagnetic layer of which the magnetization direction is pinned, and the other one of the first and second magnetic layers 12 and 14 may include a free ferromagnetic layer of which the magnetization direction can be varied according to the direction of a current applied to the variable resistance element 100.

The tunnel barrier layer 13 may include a dielectric material, for example, aluminum oxide (AlO) or magnesium oxide (MgO).

Each of the first magnetic layer 12 and the second magnetic layer 14 may include a first element exhibiting magnetism and a second element exhibiting magnetism, and the combination of the first and second elements in the magnetic layers 12 and 14 can reduce the lattice mismatch between the magnetic layers 12 and 14 and the tunnel barrier layer 13. That is, the first and second magnetic layers 12 and 14 may include, in additional to the first element exhibiting magnetism, a second element exhibiting magnetism capable of minimizing a difference in lattice constant between the first and second elements and a material forming the tunnel barrier layer 13.

The first and second magnetic layers 12 and 14 may further include a third element for reducing the specific resistance of the layers. For example, each of the first, second, and third elements may include a metallic material. For example, the first element may include iron (Fe), the second element may include nickel (Ni), and the third element may include a lanthanide series element. That is, the first and second magnetic layers 12 and 14 may include a material layer obtained by alloying a lanthanide series element in a nickel-iron compound, for example, NiFeLa alloy. Other implementations are also possible on materials included in the first to third magnetic layers. For example, the first to third magnetic layers may include any material layers capable of reducing specific resistance and maintaining a ferromagnetic characteristic while reducing the lattice mismatch between the tunnel barrier layer 13 and the magnetic layers.

The first and second magnetic layers 12 and 14 are formed of a material including the first element exhibiting magnetism and the second element exhibiting magnetism and reducing the lattice mismatch between the magnetic layers and the tunnel barrier layer 13. Thus, it is possible to use this combination of the first and second elements as the magnetic layer 12 or 14 to prevent electron scattering caused by the lattice mismatch between the magnetic layers and the tunnel barrier layer 13. Further, it is possible to improve the sheet resistance and TMR characteristics. Furthermore, the first and second magnetic layers 12 and 14 can include the third element for reducing specific resistance of the layers, which is alloyed in the first and second magnetic layers 12 and 14, the magnetic layers may have an excellent characteristic in terms of specific resistance.

The lattice mismatch between the tunnel barrier layer 13 and the first and second magnetic layers 12 and 14 will be described below in detail with reference to FIG. 5.

FIG. 2 is a cross-sectional view of an electronic device in accordance with an implementation of the disclosed technology in this patent document.

Referring to FIG. 2, the electronic device includes a substrate 21 including a switching element (not illustrated), a first interlayer dielectric layer 22, a first contact plug 23 connected to the substrate 21 through the first interlayer dielectric layer 22, a variable resistance element 200 connected to the first contact plug 23, a second interlayer dielectric layer 29 covering the variable resistance elements 200, a conductive line 31 formed over the second interlayer dielectric layer 29, and a second contact plug 30 connecting the conductive line 31 and the variable resistance element 200. Furthermore, although not illustrated, the electronic device may further include a template layer, a coupling layer, and an interface layer for improving characteristics of the respective magnetic layers in the variable resistance element 200.

The variable resistance element 200 may have a stacked structure of a first electrode 24, a first magnetic layer 25, a tunnel barrier layer 26, a second magnetic layer 27, and a second electrode 28. The first magnetic layer 25, the tunnel barrier layer 26, and the second magnetic layer 27 may have the same structure as the variable resistance element 100 illustrated in FIG. 1. The tunnel barrier layer 26 may include a dielectric material, for example, AlO or MgO.

In this example, each of the first and second magnetic layers 25 and 27 may include a first element exhibiting magnetism and a second element exhibiting magnetism, respectively. The first and second elements are structured so that their combination can reduce the lattice mismatch between the corresponding magnetic layers 25 and 27 and the tunnel barrier layer 26. That is, the first and second magnetic layers 25 and 27 may include the second element capable of minimizing a difference in lattice constant between the first and second elements and a material forming the tunnel barrier layer 26.

Furthermore, the first and second magnetic layers 25 and 27 may further include a third element for reducing sheet resistance. The first element, the second element, and the third element may include a metallic material. For example, the first element may include Fe, the second element may include Ni, and the third element may include a lanthanide series element. That is, the first and second magnetic layers 25 and 27 may include a material layer obtained by alloying a lanthanide series element in a nickel-iron compound, for example, NiFeLa. However, implementations of the above additional elements or layers in the first and second magnetic layers 25 and 27 are not limited thereto, but may include various materials capable of reducing specific resistance and maintaining a ferromagnetic characteristic while reducing the lattice mismatch between the magnetic layers 25 and 27 and the tunnel barrier layer 26.

As the first and second magnetic layers 25 and 27 are formed of a material including the first element exhibiting magnetism and the second element exhibiting magnetism and reducing the lattice mismatch between the magnetic layers and the tunnel barrier layer 26, it is possible to prevent electron scattering caused by the lattice mismatch between the magnetic layers and the tunnel barrier layer 26. Thus, it is possible to improve sheet resistance and TMR characteristics. Furthermore, as a metallic material having low specific resistance is alloyed in the first and second magnetic layers 25 and 27, it is possible to further reduce sheet resistance.

The first electrode 24, the second electrode 28, and the conductive line 31 may include a metallic layer. The metallic layer includes a conductive layer including a metal element, and may include metal, metal oxide, metal nitride, metal oxynitride, metal silicide and the like.

The first electrode 24 may serve as a bottom electrode of the variable resistance element 200. The second electrode 28 may serve as a top electrode of the variable resistance element 200. Furthermore, the second electrode 28 may serve to protect the lower layers of the variable resistance element 200 and may serve as an etch barrier for patterning the lower layers. The second electrode 28 may have a sufficient thickness to prevent a defective contact with the conductive line 31.

The electronic device may further include a substrate 21 having a predetermined structure, for example, a switching element and the like, a first interlayer dielectric layer 22 formed over the substrate 21, and a first contact plug 23 electrically connecting one end of the switching element to the variable resistance element 200 through the first interlayer dielectric layer 22. The variable resistance element 200 may be formed over the first interlayer dielectric layer 22. Furthermore, the electronic device may further include a second interlayer dielectric layer 29 buried between the variable resistance elements 200, a conductive line 31 formed over the second interlayer dielectric layer 29, and a second contact plug 30 electrically connecting the variable resistance element 200 and the conductive line 31 through the second interlayer dielectric layer 29 over the variable resistance element 200.

In the electronic device including a plurality of unit cells, the switching element may be disposed in each unit cell for selecting a specific unit cell among the plurality of unit cells, and may include a transistor, a diode and the like. One end of the switching element may be electrically connected to the first contact plug 23, and the other end of the switching element may be electrically connected to a wiring (not illustrated), for example, a source line.

The first contact plug 23 and the second contact plug 29 may include a semiconductor layer or metallic layer, and the variable resistance element 200 may have a greater critical dimension (CD) or area than the first contact plug 23 and the second contact plug 29.

As the first and second magnetic layers 25 and 27 are formed of a material including the first element exhibiting magnetism and the second element exhibiting magnetism and reducing the lattice mismatch between the magnetic layers and the tunnel barrier layer 26, it is possible to prevent electron scattering caused by the lattice mismatch between the magnetic layers and the tunnel barrier layer 26. Thus, it is possible to improve sheet resistance and TMR characteristics. Furthermore, as the third element for reducing specific resistance is alloyed in the first and second magnetic layers 25 and 27, the magnetic layers may have an excellent characteristic in terms of specific resistance.

FIGS. 3A to 3D are cross-sectional views illustrating a method for fabricating an electronic device in accordance with an implementation of the disclosed technology in this patent document.

Referring to FIG. 3A, a substrate 21 including a predetermined structure, for example, a switching element (not illustrated) is prepared. The switching element serves to select a specific unit cell among a plurality of unit cells in the electronic device, and may include a transistor, a diode and the like. One end of the switching element may be electrically connected to the first contact plug 23 to be described below, and the other end of the switching element may be electrically connected to a wiring (not illustrated), for example, a source line.

A first interlayer dielectric layer 22 is formed over the substrate 21. The first interlayer dielectric layer 22 may include any single layer of oxide, nitride, and oxynitride or a stacked layer thereof.

A first contact plug 23 is formed to be electrically connected to one end of the switching element (not illustrated) through the first interlayer dielectric layer 22. The first contact plug 23 may serve to electrically connect the switching element to a variable resistance element to be formed through a subsequent process, and may serve as an electrode for the variable resistance element, for example, a bottom electrode. The first contact plug 23 may be may be formed of a semiconductor layer or metallic layer. The semiconductor layer may include silicon, and the metallic layer may include metal, metal oxide, metal nitride, metal oxynitride, metal silicide and the like.

The first contact plug 23 may be formed through the following processes. The first interlayer dielectric layer 22 is selectively etched to form a contact hole exposing one end of the switching element. A conductive material is formed on the entire surface of the resultant structure so as to gap-fill the contact hole. An isolation process is performed to electrically isolate the adjacent first contact plugs 23. The isolation process may be performed by etching or polishing the conductive material formed on the entire surface of the resultant structure through a blanket etch process (for example, etch-back process) or chemical mechanical polishing (CMP) process, until the first interlayer dielectric layer 22 is exposed.

Referring to FIG. 3B, a conductive layer 24A is formed over the first interlayer dielectric layer 22 including the first contact plug 23. The conductive layer 24A serves as a first electrode of a variable resistance element to be formed through a subsequent process, that is, a bottom electrode and may be formed of a metallic layer.

A first magnetic layer 25A, a tunnel barrier layer 26A, and a second magnetic layer 27A are stacked over the conductive layer 24A.

The tunnel barrier layer 26A interposed between the two magnetic layers 25A and 27A may include a dielectric material, or a metal oxide. For example, the tunnel barrier layer 26A may include AlO or MgO. The tunnel barrier layer 26A may be formed through physical vapor deposition (PVD) or atomic layer deposition (ALD). The PVD may include RF sputtering or reactive sputtering.

The first magnetic layer 25A and the second magnetic layer 27A may include a first element exhibiting magnetism and a second element having magnetism and reducing the lattice mismatch between the magnetic layers and the tunnel barrier layer 26A. That is, the first and second magnetic layers 25A and 27A may include the second element capable of reducing a difference in lattice constant between materials of the first and second magnetic layer including the first and second elements and the material of the tunnel barrier layer 26A.

The first and second magnetic layers 25A and 27A may further include a third element for reducing specific resistance of the layers. For example, each of the first element, the second element, and the third element may include a metallic material. For example, the first element may include iron (Fe), the second element may include nickel (Ni), and the third element may include a lanthanide series element. That is, the first and second magnetic layers 25A and 27A may include a material layer obtained by alloying a lanthanide series element in a nickel-iron compound, for example, NiFeLa alloy. Other implementations are also possible and may include any material layers capable of reducing specific resistance and maintaining a ferromagnetic characteristic while reducing the lattice mismatch between the magnetic layers 25A and 27A and the tunnel barrier layer 26.

The first and second magnetic layers 25A and 27A may be in-situ formed through PVD. When the first and second magnetic layers 25A and 27A are formed, the composition of elements within the layers may be changed to control the lattice constant. Thus, the lattice mismatch between the first and second magnetic layers 25A and 27A and the tunnel barrier layer 26A may be further reduced.

A second electrode 28 is formed over the second magnetic layer 27A. The second electrode 28 may be formed by forming a conductive layer over the second magnetic layer 27A and then patterning the conductive layer through a mask pattern. At this time, a dry etch process may be applied.

The second electrode 28 serves as a top electrode of a variable resistance element to be formed through a subsequent process, and may be formed of a metallic layer. Furthermore, the second electrode 28 may serve as an etch barrier for forming the variable resistance element.

As the first and second magnetic layers 25A and 27A are formed of a material including the first element exhibiting magnetism and the second element exhibiting magnetism and this combination of the first and second elements can reduce the lattice mismatch between the magnetic layers and the tunnel barrier layer 26A. As such, it is possible to prevent electron scattering caused by the lattice mismatch between the magnetic layers and the tunnel barrier layer 26A. Thus, it is possible to improve the sheet resistance and TMR characteristics of the variable resistance element to be formed during the subsequent process. Furthermore, as a metallic material having low specific resistance is alloyed in the first and second magnetic layers 25A and 27A, it is possible to further reduce sheet resistance of the variable resistance element.

Referring to FIG. 3C, by using the second electrode 28 as an etch barrier, the second magnetic layer 27A, the tunnel barrier layer 26A, the first magnetic layer 25A, and the conductive layer 24A are sequentially etched. Although in the present implementation, the second electrode 28 is used as an etch barrier, the mask pattern for forming the second electrode 28 may be used as an etch barrier for forming the variable resistance element. For this, the mask pattern needs to be remained without being removed.

Then, the variable resistance element 200 is formed to have a stacked structure of the first electrode 24, the first magnetic layer 25, the tunnel barrier layer 26, the second magnetic layer 27, and the second electrode 28. The variable resistance element 200 may be formed in a line type extended in a direction that a conductive line to be formed through a subsequent process is extended, or a plurality of pillar-type variable resistance elements 200 may be arranged to be spaced at a predetermined distance from one another in the direction that the conductive line is extended. Furthermore, the variable resistance element 200 may be formed to have a CD or area to cover the contact plug 23.

Although not illustrated, a spacer may be formed on the sidewall of the variable resistance element 200 during a subsequent process.

Referring to FIG. 3D, a second interlayer dielectric layer 29 is formed over the first interlayer dielectric layer 22. The second interlayer dielectric layer 29 may be formed to have a sufficient thickness to fill the space between the variable resistance elements 200. For example, the second interlayer dielectric layer 29 may have such a thickness that the top surface of the second interlayer dielectric layer 29 is positioned at a higher level than the top surface of the variable resistance element 200. The second interlayer dielectric layer 29 may be formed of the same material as the first interlayer dielectric layer 22. The second interlayer dielectric layer 29 may include a single layer of oxide, nitride, or oxynitride or a stacked layer of two or more layers by using oxide, nitride, or oxynitride.

A second contact plug 30 is formed to be electrically connected to the variable resistance element 200 through the second interlayer dielectric layer 29 over the variable resistance element 200. The second contact plug 30 may serve to electrically connect the variable resistance element 200 to a conductive line to be formed through a subsequent process, and may serve as an electrode for the variable resistance element, for example, the top electrode. The second contact plug 30 may be formed of a semiconductor layer or metallic layer. The semiconductor layer may include silicon. The metallic layer is a material layer containing metal, and may include metal, metal oxide, metal nitride, metal oxynitride, metal silicide and the like.

The second contact plug 30 may be through the following series of processes: the second interlayer dielectric layer 29 is selectively etched to form a contact hole exposing one end of the variable resistance element 200, a conductive material is formed on the entire surface of the resultant structure so as to gap-fill the contact hole, and an isolation process is performed to electrically isolate the adjacent second contact plugs 30. The isolation process may be performed by etching or polishing the conductive material formed on the entire surface of the resultant structure through a blanket etch process (for example, etch-back process) or chemical mechanical polishing (CMP) process, until the second interlayer dielectric layer 29 is exposed.

The conductive line 31 is formed over the second interlayer dielectric layer 29. The conductive line 31 is connected to the second contact plug 30, and electrically connected to the variable resistance element 200 through the second contact plug 30.

FIGS. 4A and 4B and FIGS. 5A and 5B are views for facilitating the understanding of the concept of the variable resistance element provided in accordance with the present implementation. FIGS. 4A and 4B show views explaining a variable resistance element in accordance with a comparative example. FIGS. 5A and 5B show views explaining a variable resistance element in accordance with the present implementation. The comparative example and the present implementation are provided as only examples for comparison. The present implementation is not limited thereto, but may include any magnetic layers of a variable resistance element, which are capable of minimizing the lattice mismatch between the magnetic layers and a tunnel barrier layer.

In the comparative example of FIGS. 4A and 4B, CoFeB is applied as the magnetic layers, and MgO is applied as the tunnel barrier layer. At this time, a lattice constant of Co—Fe in CoFeB applied as the magnetic layers is 0.21 nm, which corresponds to 50% of the lattice constant of MgO, i.e., 0.42 nm. In this example, the lattice mismatch is significant and undesirable. As illustrated in the conceptual view, the lattice mismatch causes a compressive stress to the tunnel barrier layer to cause undesired electron scattering. Accordingly, sheet resistance may increase, and TMR may decrease.

In the present implementation of FIGS. 5A and 5B, NiFeLa alloy is applied as the magnetic layers. In this case, since a lattice constant of Ni—Fe is 0.34 nm, the lattice mismatch between the magnetic layers and the tunnel barrier layer decreases to half of the comparative example. The decrease of the lattice mismatch reduces compressive stress applied to the tunnel barrier layer as illustrated in the conceptual view, thereby reducing electron scattering caused by the compressive stress. Thus, sheet resistance may decrease, and TMR may increase. Furthermore, among the elements of the respective magnetic layers, Ni has lower specific resistance than Co, and La has much lower specific resistance than B. Thus, sheet resistance is further decreased. Furthermore, in the case of La, diffusion does not occur. Thus, since the characteristics of the layers adjacent to each other at the upper and lower parts are not changed, the TMR characteristic may be further improved. In the present implementation, NiFeLa alloy is applied. However, other implementations are also possible that the magnetic layers include various metal elements for reducing specific resistance within the layers, for example, lanthanide series elements.

In accordance with the above-described implementations, the lattice mismatch between the tunnel barrier layer and the magnetic layers may be minimized to reduce compressive stress applied to the tunnel barrier layer and electron scattering caused by the compressive stress. Thus, the sheet resistance and TMR characteristics may be improved.

The above and other memory circuits or semiconductor devices based on the disclosed technology can be used in a range of devices or systems. FIGS. 6-10 provide some examples of devices or systems that can implement the memory circuits disclosed herein.

FIG. 6 is an example of configuration diagram of a microprocessor implementing memory circuitry based on the disclosed technology.

Referring to FIG. 6, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored.

The memory unit 1010 may include one or more of the above-described semiconductor devices in accordance with the implementations. For example, the memory unit 1010 may include a variable resistance element including first and second magnetic layers having a lanthanide series element alloyed in a nickel-iron compound and a tunnel barrier layer interposed between the first and second magnetic layers. The first and second magnetic layers may include NiFeLa alloy. The tunnel barrier layer may include aluminum oxide (AlO) or magnesium oxide (MgO). The memory unit 1010 may include a variable resistance element including first and second magnetic layers formed over a substrate including a switching element and having a lanthanide series element alloyed in a nickel-iron compound, a tunnel barrier layer interposed between the first and second magnetic layers, and a conducive line connected to the variable resistance element. The first and second magnetic layers may include NiFeLa alloy. The tunnel barrier layer may include AlO or MgO.

Through this, as the first and second magnetic layers are formed of a material including the first element having magnetic properties and the second element having magnetic properties, which reduce the lattice mismatch between the magnetic layers and the tunnel barrier layer, it is possible to prevent electron scattering caused by the lattice mismatch between the magnetic layers and the tunnel barrier layer. Thus, it is possible to improve sheet resistance and TMR characteristics. Furthermore, as the third element for reducing specific resistance is alloyed in the first and second magnetic layers, the magnetic layers may have an excellent characteristic in terms of specific resistance. Furthermore, as a metallic material having low specific resistance is alloyed in the first and second magnetic layers, it is possible to further reduce sheet resistance. As a consequence, performance characteristics of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

FIG. 7 is an example of configuration diagram of a processor implementing memory circuitry based on the disclosed technology.

Referring to FIG. 7, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include a variable resistance element including first and second magnetic layers having a lanthanide series element alloyed in a nickel-iron compound, and a tunnel barrier layer interposed between the first and second magnetic layers. The first and second magnetic layers may include NiFeLa alloy. The tunnel barrier layer may include aluminum oxide (AlO) or magnesium oxide (MgO). The memory unit 1010 may include a variable resistance element including first and second magnetic layers formed over a substrate including a switching element and having a lanthanide series element alloyed in a nickel-iron compound, a tunnel barrier layer interposed between the first and second magnetic layers, and a conducive line connected to the variable resistance element. The first and second magnetic layers may include NiFeLa alloy. The tunnel barrier layer may include AlO or MgO.

Through this, as the first and second magnetic layers are formed of a material including the first element exhibiting magnetism and the second element exhibiting magnetism and reducing the lattice mismatch between the magnetic layers and the tunnel barrier layer, it is possible to prevent electron scattering caused by the lattice mismatch between the magnetic layers and the tunnel barrier layer. Thus, it is possible to improve sheet resistance and TMR characteristics. Furthermore, as the third element for reducing specific resistance is alloyed in the first and second magnetic layers, the magnetic layers may have an excellent characteristic in terms of specific resistance. Furthermore, as a metallic material having low specific resistance is alloyed in the first and second magnetic layers, it is possible to further reduce sheet resistance. As a consequence, performance characteristics of the cache memory unit 1120 may be improved. Although it was shown in FIG. 7 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

FIG. 6 is an example of configuration diagram of a system implementing memory circuitry based on the disclosed technology.

Referring to FIG. 6, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include a variable resistance element including first and second magnetic layers having a lanthanide series element alloyed in a nickel-iron compound, and a tunnel barrier layer interposed between the first and second magnetic layers. The first and second magnetic layers may include NiFeLa alloy. The tunnel barrier layer may include aluminum oxide (AlO) or magnesium oxide (MgO). The memory unit 1010 may include a variable resistance element including first and second magnetic layers formed over a substrate including a switching element and having a lanthanide series element alloyed in a nickel-iron compound, and a tunnel barrier layer interposed between the first and second magnetic layers, and a conducive line connected to the variable resistance element. The first and second magnetic layers may include NiFeLa alloy. The tunnel barrier layer may include AlO or MgO.

Through this, as the first and second magnetic layers are formed of a material including the first element having magnetic properties and the second element having magnetic properties and reducing the lattice mismatch between the magnetic layers and the tunnel barrier layer, it is possible to prevent electron scattering caused by the lattice mismatch between the magnetic layers and the tunnel barrier layer. Thus, it is possible to improve sheet resistance and TMR characteristics. Furthermore, as the third element for reducing specific resistance is alloyed in the first and second magnetic layers, the magnetic layers may have an excellent characteristic in terms of specific resistance. Furthermore, as a metallic material having low specific resistance is alloyed in the first and second magnetic layers, it is possible to further reduce sheet resistance. As a consequence, performance characteristics of the main memory device 1220 may be improved.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include a variable resistance element including first and second magnetic layers having a lanthanide series element alloyed in a nickel-iron compound, and a tunnel barrier layer interposed between the first and second magnetic layers. The first and second magnetic layers may include NiFeLa alloy. The tunnel barrier layer may include aluminum oxide (AlO) or magnesium oxide (MgO). The memory unit 1010 may include a variable resistance element including first and second magnetic layers formed over a substrate including a switching element and having a lanthanide series element alloyed in a nickel-iron compound, a tunnel barrier layer interposed between the first and second magnetic layers, and a conducive line connected to the variable resistance element. The first and second magnetic layers may include NiFeLa alloy. The tunnel barrier layer may include AlO or MgO.

Through this, as the first and second magnetic layers are formed of a material including the first element having magnetic properties and the second element having magnetic properties and reducing the lattice mismatch between the magnetic layers and the tunnel barrier layer, it is possible to prevent electron scattering caused by the lattice mismatch between the magnetic layers and the tunnel barrier layer. Thus, it is possible to improve sheet resistance and TMR characteristics. Furthermore, as the third element for reducing specific resistance is alloyed in the first and second magnetic layers, the magnetic layers may have an excellent characteristic in terms of specific resistance. Furthermore, as a metallic material having low specific resistance is alloyed in the first and second magnetic layers, it is possible to further reduce sheet resistance. As a consequence, performance characteristics of the auxiliary memory device 1230 may be improved.

Also, the auxiliary memory device 1230 may further include a data storage system (see the reference numeral 1300 of FIG. 6) such as a magnetic tape, a magnetic disk, a laser disk using optics, a magneto-optical disc based on both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 6) such as a magnetic tape, a magnetic disk, a laser disk using optics, a magneto-optical disc based on both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 7 is an example of configuration diagram of a data storage system implementing memory circuitry based on the disclosed technology.

Referring to FIG. 7, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 may include a variable resistance element including first and second magnetic layers having a lanthanide series element alloyed in a nickel-iron compound, and a tunnel barrier layer interposed between the first and second magnetic layers. The first and second magnetic layers may include NiFeLa alloy. The tunnel barrier layer may include aluminum oxide (AlO) or magnesium oxide (MgO). The memory unit 1010 may include a variable resistance element including first and second magnetic layers formed over a substrate including a switching element and having a lanthanide series element alloyed in a nickel-iron compound, and a tunnel barrier layer interposed between the first and second magnetic layers, and a conducive line connected to the variable resistance element. The first and second magnetic layers may include NiFeLa alloy. The tunnel barrier layer may include AlO or MgO. Through this, as the first and second magnetic layers are formed of a material including the first element exhibiting magnetism and the second element exhibiting magnetism and reducing the lattice mismatch between the magnetic layers and the tunnel barrier layer, it is possible to prevent electron scattering caused by the lattice mismatch between the magnetic layers and the tunnel barrier layer. Thus, it is possible to improve sheet resistance and TMR characteristics. Furthermore, as the third element for reducing specific resistance is alloyed in the first and second magnetic layers, the magnetic layers may have an excellent characteristic in terms of specific resistance. Furthermore, as a metallic material having low specific resistance is alloyed in the first and second magnetic layers, it is possible to further reduce sheet resistance. As a consequence, performance characteristics of the temporary storage device 1340 may be improved.

FIG. 10 is an example of configuration diagram of a memory system implementing memory circuitry based on the disclosed technology.

Referring to FIG. 10, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include a variable resistance element including first and second magnetic layers having a lanthanide series element alloyed in a nickel-iron compound, and a tunnel barrier layer interposed between the first and second magnetic layers. The first and second magnetic layers may include NiFeLa alloy. The tunnel barrier layer may include aluminum oxide (AlO) or magnesium oxide (MgO). The memory unit 1010 may include a variable resistance element including: first and second magnetic layers formed over a substrate including a switching element and having a lanthanide series element alloyed in a nickel-iron compound, a tunnel barrier layer interposed between the first and second magnetic layers, and a conducive line connected to the variable resistance element. The first and second magnetic layers may include NiFeLa alloy. The tunnel barrier layer may include AlO or MgO.

Through this, as the first and second magnetic layers are formed of a material including the first element exhibiting magnetism and the second element exhibiting magnetism and reducing the lattice mismatch between the magnetic layers and the tunnel barrier layer, it is possible to prevent electron scattering caused by the lattice mismatch between the magnetic layers and the tunnel barrier layer. Thus, it is possible to improve sheet resistance and TMR characteristics. Furthermore, as the third element for reducing specific resistance is alloyed in the first and second magnetic layers, the magnetic layers may have an excellent characteristic in terms of specific resistance. Furthermore, as a metallic material having low specific resistance is alloyed in the first and second magnetic layers, it is possible to further reduce sheet resistance. As a consequence, performance characteristics of the memory 1410 may be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more above-described semiconductor devices in accordance with the implementations. For example, the memory buffer memory 1440 may include a variable resistance element including first and second magnetic layers having a lanthanide series element alloyed in a nickel-iron compound, and a tunnel barrier layer interposed between the first and second magnetic layers. The first and second magnetic layers may include NiFeLa alloy. The tunnel barrier layer may include aluminum oxide (AlO) or magnesium oxide (MgO). The buffer memory 1440 may include a variable resistance element including first and second magnetic layers formed over a substrate including a switching element and having a lanthanide series element alloyed in a nickel-iron compound, a tunnel barrier layer interposed between the first and second magnetic layers, and a conducive line connected to the variable resistance element. The first and second magnetic layers may include NiFeLa alloy. The tunnel barrier layer may include AlO or MgO.

The buffer memory 1440 for temporarily storing data may include one or more of the above-described semiconductor devices in accordance with the implementations. The buffer memory 1440 may include a substrate including a first region and a second region; a stack structure in which a first gate and a gate protection layer are stacked, wherein a part of the stack structure is buried in the substrate and a remainder of the stack structure protrudes above the substrate, in the first region; a conductive plug disposed at a side of the stack structure, on the substrate of the first region; and a second gate disposed on the substrate of the second region. Through this, characteristics of a transistor of the buffer memory 1440 may be improved, and the degree of process difficulty in fabricating the buffer memory 1440 may be reduced by substantially preventing the occurrence of a step difference between regions difference from each other, thereby improving the data storage characteristics of the buffer memory 1440 in case that the transistor is coupled to a memory element, for example, a resistance variable element. As a consequence, a fabrication process of the memory system 1400 may become easy and the performance characteristics of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

As is apparent from the above descriptions, in the semiconductor device and the method for fabricating the same in accordance with the implementations, patterning of a resistance variable element is easy, and it is possible to secure the characteristics of the resistance variable element.

Features in the above examples of electronic devices or systems in FIGS. 6-10 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document includes many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. A variable resistance element comprising:
first and second magnetic layers including a nickel-iron compound and a lanthanide series element alloyed in the nickel-iron compound; and
a tunnel barrier layer interposed between the first and second magnetic layers.

2. The variable resistance element according to claim 1, wherein the first and second magnetic layers include NiFeLa alloy.

3. The variable resistance element according to claim 1, wherein the tunnel barrier layer include aluminum oxide (AlO) or magnesium oxide (MgO).

4. The variable resistance element according to claim 1, further comprising:
a conducive line connected to the variable resistance element.

5. An electronic device comprising:
a semiconductor memory including a variable resistance element; and
a conductive line connected to the variable resistance element,
wherein the semiconductor memory includes:
first and second magnetic layers including a nickel-iron compound and a lanthanide series element alloyed in the nickel-iron compound; and
a tunnel barrier layer interposed between the first and second magnetic layers.

6. The electronic device according to claim 5, wherein the first and second magnetic layers include NiFeLa alloy.

7. The electronic device according to claim 5, wherein the tunnel barrier layer include aluminum oxide (AlO) or magnesium oxide (MgO).

8. The electronic device according to claim 5, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the semiconductor memory is part of the memory unit in the microprocessor.

9. The electronic device according to claim 5, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory is part of the cache memory unit in the processor.

10. The electronic device according to claim 5, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the semiconductor memory is part of the auxiliary memory device or the main memory device in the processing system.

11. The electronic device according to claim 5, further comprising a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the semiconductor memory is part of the storage device or the temporary storage device in the data storage system.

12. The electronic device according to claim 5, further comprising a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the semiconductor memory is part of the memory or the buffer memory in the memory system.

13. A variable resistance element comprising:
first and second magnetic layers, each magnetic layer including first and second elements exhibiting magnetism; and
a tunnel barrier layer interposed between the first and second magnetic layers,
wherein the first and second elements are selected to cause a corresponding magnetic layer to have a reduced or minimized lattice mismatch between the first and second magnetic layers and the tunnel barrier layer.

14. The variable resistance element according to claim 13, wherein the first and second elements include a nickel-iron compound.

15. The variable resistance element according to claim 13, wherein the first and second magnetic layers further includes a third element to reduce a specific resistance of each layer.

16. The variable resistance element according to claim 15, wherein the third element include a lanthanide series element.

17. The variable resistance element according to claim 16, wherein the first and second magnetic layers include NiFeLa alloy.

18. The variable resistance element according to claim 13, wherein the tunnel barrier layer includes aluminum oxide (AlO) or magnesium oxide (MgO).
